(19) United States
(12) Patent Application Publication
(10) Pub. No.: US 2026/0169067 A1
(43) Pub. Date: Jun. 18, 2026

(54) METHOD AND DEVICE FOR PREDICTING WAFER TEST DATA

(71) Applicant: DigWise Technology Corporation, LTD, Hsinchu County (TW)

(72) Inventors: Shih-Hao Chen, Hsinchu County (TW); Liang-Yu Chen, Hsinchu County (TW)

(73) Assignee: DigWise Technology Corporation, LTD, Hsinchu County (TW)

(21) Appl. No.: 18/981,655

(22) Filed: Dec. 16, 2024

(51) Int. Cl. G01R 31/3183; G01R 31/317

(52) U.S. Cl. CPC G01R 31/318307; G01R 31/31703; G01R 31/31704

(57) ABSTRACT

Provided are a method and a related electronic device for predicting wafer test data. The method includes: a wafer acceptance test (WAT) data of a wafer is pre-processed to convert a position information of the WAT data in the wafer to a positional embedding vector, and the WAT data has a first quantity of data points; a chip probing (CP) data and the positional embedding vector of the wafer are input into an artificial intelligence model to allow the artificial intelligence model to generate a predicted WAT data of the wafer. The predicted WAT data has a second quantity of data points greater than the first quantity.

### BACKGROUND

### Technical Field

The disclosure relates to a method and a device, in particular to a method and a related electronic device thereof for predicting wafer test data.

### Description of Related Art

Electrical characteristics on a wafer often have a complex distribution. In many test conditions, it is difficult to fully cover or reflect these characteristics with limited test data. Therefore, how to precisely acquire the electrical characteristic distribution of the entire wafer using limited test data has become an important topic in the field.

### SUMMARY

The disclosure provides a method and an electronic device for predicting wafer test data, which can be configured to predict data of an electrical characteristic distribution on a wafer.

The method for predicting wafer test data provided by the disclosure includes: a pre-processing is performed on a wafer acceptance test (WAT) data of a wafer to convert multiple position information of the WAT data on the wafer to multiple positional embedding vectors, and the WAT data has a first quantity of data points; and a chip probing (CP) data and the positional embedding vectors of the wafer are input into an artificial intelligence model to allow the artificial intelligence model to generate a predicted WAT data of the wafer, and the predicted WAT data has a second quantity of data points greater than the first quantity.

The electronic device of the disclosure is configured to predict wafer data. The electronic device includes: a memory and a processing circuit. The memory stores a command. The processing circuit is coupled to the memory and is configured to access the command to execute an artificial intelligence model for: performing a pre-processing on a wafer acceptance test (WAT) data of a wafer to convert position information of the WAT data on the wafer to positional embedding vectors, and the WAT data has a first quantity of data points; and inputting a chip probing (CP) data and the positional embedding vectors of the wafer into the artificial intelligence model to allow the artificial intelligence model to generate a predicted WAT data of the wafer, and the predicted WAT data has a second quantity of data points greater than the first quantity.

Based on the above, the method and the electronic device for predicting wafer test data provided by the disclosure can predict the electrical characteristic distribution on the wafer through less test data.

### BRIEF DESCRIPTION OF THE DRAWINGS

FIG. 1 is a block diagram of an electronic device according to an embodiment of the disclosure.

FIG. 2 is a flow chart of a prediction method according to an embodiment of the disclosure.

FIG. 3 is a position distribution diagram of test data on a wafer according to an embodiment of the disclosure.

FIG. 4 is a schematic diagram of an artificial intelligence model and a pre-processing according to an embodiment of the disclosure.

FIG. 5 is a distribution diagram of test data on multiple wafers according to an embodiment of the disclosure.

FIG. 6 is a schematic diagram of an artificial intelligence model and a pre-processing according to an embodiment of the disclosure.

FIG. 7 is a flow chart of a training method for an artificial intelligence model.

### DESCRIPTION OF THE EMBODIMENTS

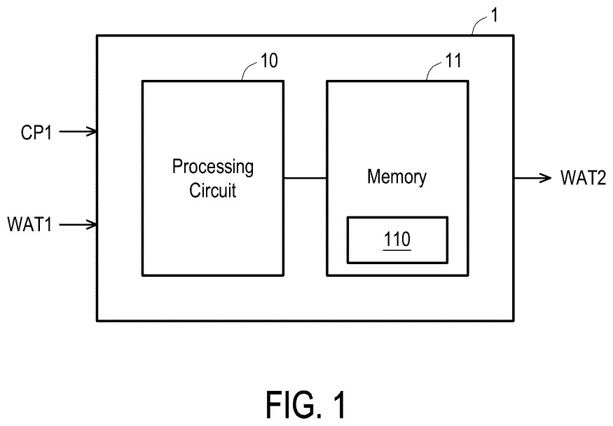

FIG. 1 is a block diagram of an electronic device 1 according to an embodiment of the disclosure. The electronic device 1 in FIG. 1 includes a processing circuit 10 and a memory 11. The memory 11 stores a command 110, and the electronic device 1 may access the command 110 in the memory 11. Though not clearly shown in FIG. 1, the memory 11 also stores related weight data of a pre-processing and an artificial intelligence model. Therefore, the processing circuit 10 may execute the artificial intelligence model to predict the distribution of test data on an entire surface of a wafer according to a chip probing (CP) data CP1 and a wafer acceptance test (WAT) data WAT1 that are received to generate a predicted WAT data WAT2. Specifically, through the CP data CP1 with more data points, the processing circuit 10 may accurately predict a complete distribution of the predicted WAT data WAT2 on the wafer by the WAT data WAT1 that is relatively sparse.

In some embodiments, the processing circuit 10 may be, for example, a central processing unit (CPU), or other programmable general-purpose or special-purpose micro control unit (MCU), microprocessor, digital signal processor (DSP), programmable controller, application specific integrated circuit (ASIC), graphics processing unit (GPU), neural processing unit (NPU), arithmetic logic unit (ALU), complex programmable logic device (CPLD), field programmable gate array (FPGA), any other types of integrated circuits, state machines, processors based on advanced RISC machine (ARM), or other similar elements or a combination of the foregoing elements.

In some embodiments, the memory 11 may be, for example, any type of fixed or movable random access memory (RAM), read-only memory (ROM), flash memory, hard disk drive (HDD), solid state drive (SSD) or similar elements or a combination of the foregoing elements, and is configured to store multiple modules or applications that may be executed by the processing circuit 10. In the embodiment, an artificial intelligence model 110 may be stored in the memory 11, and the functions thereof will be described later.

In some embodiments, the artificial intelligence model 110 may be a machine learning model, such as an MLP (multilayer perceptron), a VAE (variational autoencoder), a cVAE (conditional variational autoencoder), a U-Net or other models with a similar architecture.

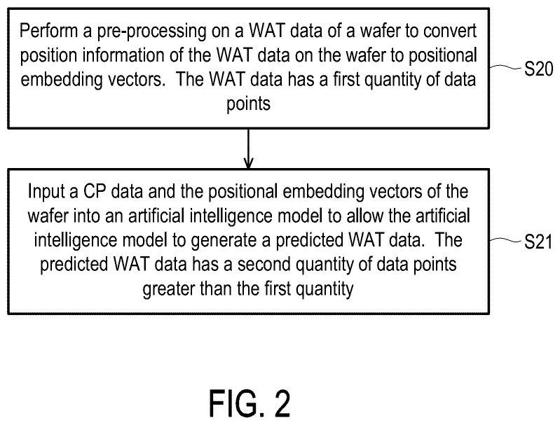

FIG. 2 is a flow chart of a prediction method according to an embodiment of the disclosure. The method may be applied to the electronic device 1 shown in FIG. 1, and is executed to predict the distribution of test data on the entire surface of the wafer based on the WAT data WAT1 and the CP data CP1 of the same wafer that are received, thereby generating the WAT data WAT2.

The prediction method in FIG. 2 includes steps S20 and S21. In step S20, the processing circuit 10 may perform a pre-processing on the WAT data WAT1 of a wafer to convert position information corresponding to the WAT data WAT1 in the wafer to positional embedding vectors. Specifically, the WAT data WAT1 that is pre-processed is relatively sparse, records a mean value message on the wafer and only has a first quantity of data points. In some embodiments, only thirteen data points are actually measured on a wafer to obtain WAT data. In other embodiments, the first quantity of data points may be increased or decreased according to different needs.

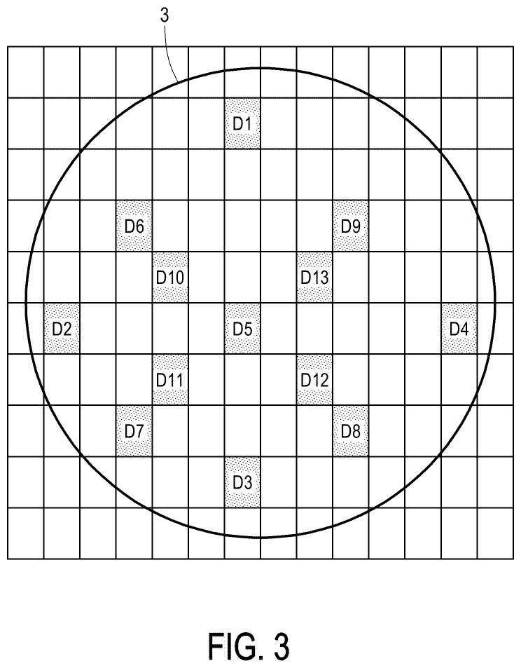

FIG. 3 is a position distribution diagram of a test data WAT1 on a wafer 3 according to an embodiment of the disclosure. Specifically, the wafer 3 shown in FIG. 3 is divided into multiple squares based on the size of a unit photomask. In the process of making the wafer 3, a processing may be performed in sequence according to the size of the unit photomask. After the wafer 3 is completed, a wafer acceptance test (WAT), a chip probing (CP) and a final test (FT) are performed.

In the CP testing, each die on the entire wafer 3 is probed for testing, with the goal of ensuring that the electrical characteristics (such as current, voltage, timing, or other functional verifications) of each die on the entire wafer 3 meet the basic design specifications.

On the wafer 3, the boundary line between each unit photomask is provided with a scribe line. The WAT testing may obtain test data through disposing test keys on the scribe lines. Specifically, the test keys include various elements, such as N-type transistors (NMOS), P-type transistors (PMOS), resistors, capacitors, etc. of different sizes. The WAT testing may test the elements to obtain electrical parameters thereof (such as on-current, on-resistance, breakdown voltage, threshold voltage, etc.). Therefore, the WAT testing may obtain test data at different positions through disposing the test keys at multiple positions of the wafer 3 shown in FIG. 3.

Finally, after the dies on the wafer 3 are packaged, the FT testing may be performed next. Packaged dies may be performed through an automatic test equipment (ATE) and/or a system level test (SLT). Generally speaking, the FT testing may be used to detect and ensure that the packaged dies are functionally normal.

Back to the WAT testing, as previously mentioned, since the test keys may obtain more detailed test data, the WAT test keys usually have a larger size. Therefore, in the official mass production stage of the wafer, only a small quantity of test keys may be disposed on the wafer 3. In the embodiment of FIG. 3, only thirteen sets of test keys are disposed on the wafer 3, which are respectively disposed at the marked thirteen unit photomask positions D1 to D13.

Furthermore, since the WAT testing may only obtain test data of part of the positions on the wafer 3, how to use the limited test data to determine the complete electrical characteristic distribution on the entire wafer 3 has become a main goal of the prediction method in FIG. 2.

Furthermore, in step S20, the processing circuit 10 performs the pre-processing on the WAT data WAT1, encodes the position information thereof as the positional embedding vectors and inputs into the artificial intelligence model 110. In this way, the artificial intelligence model 110 may capture position-related information during the prediction process and perform position-related predictions based thereon. In some embodiments, the pre-processing may be a sinusoidal positioning embedding or using an MLP to generate the positional embedding vectors.

Next, in step S21, the artificial intelligence model 110 receives the CP data CP1 and the positional embedding vectors and performs computation, thereby predicting the WAT data WAT2 on the entire wafer. Specifically, thanks to the positional embedding vectors (from the test data WAT1 with a small quantity of sampling points) and the CP data (such as output impedance RO or leakage current SIDD) CP1 with more data points that may fully characterize the uniformity of the wafer, the artificial intelligent model may predict the complete test data distribution on the entire wafer 3 and generate the corresponding predicted WAT data WAT2. In other words, a second quantity of data points in the predicted WAT data WAT2 may be more than the first quantity of data points in the WAT data WAT1, that is, having a higher position resolution. In some embodiments, the CP data CP1 may have data points of a full map of the wafer, and the predicted WAT data WAT2 generated may have the same quantity of data points as the CP data CP1. In some embodiments, the artificial intelligence model may be an MLP, a VAE, a cVAE, a U-Net model, etc.

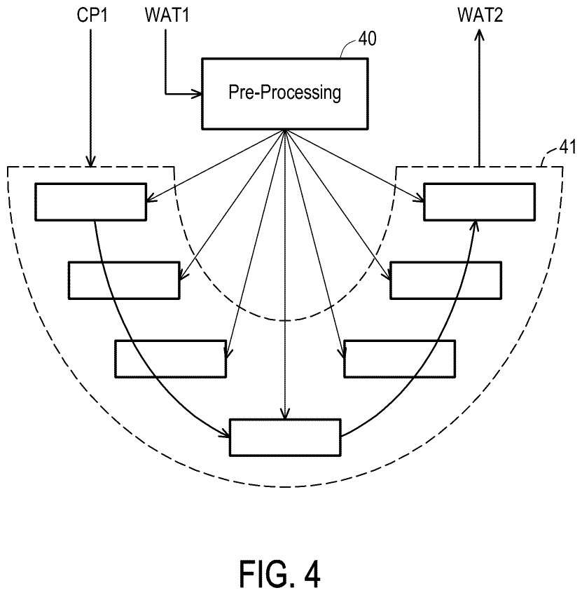

FIG. 4 is a schematic diagram of an artificial intelligence model 41 and a pre-processing 40 according to an embodiment of the disclosure. As shown in the figure, FIG. 4 includes the pre-processing 40 and the artificial intelligence model 41. The test data WAT1 may be sent to the pre-processing 40. After the pre-processing 40 has performed computation, the position of the test data WAT1 may be represented by positional embedding vectors.

In the embodiment, the artificial intelligence model 41 is a multilayer perceptron model. Though not explicitly shown in the figure, the positional embedding vectors are multiple residual network (ResNet) units provided therein to allow the artificial intelligence model 41 to combine the CP data CP1 and the WAT data WAT1 to perform computation according to information such as mean value messages, positional relationships, or sequence thereof, thereby generating the predicted WAT data WAT2.

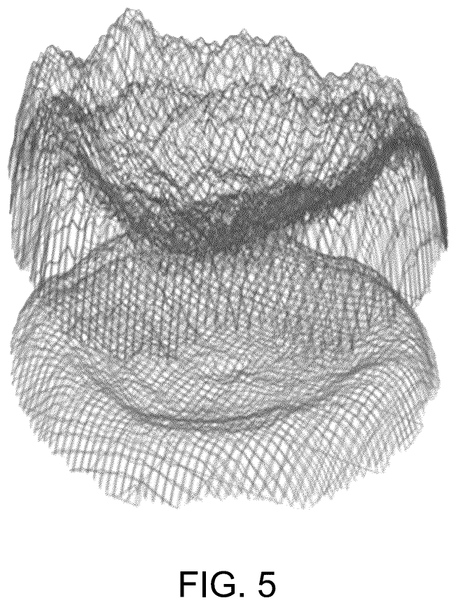

FIG. 5 is a distribution diagram of test data on multiple wafers according to an embodiment of the disclosure. FIG. 5 shows a test data distribution diagram of three wafers. As shown in the figure, the test data of the three wafers generally shows a donut-shaped distribution trend that protrudes around the wafer and slightly concaves at the center of the wafer. In some embodiments, in addition to the donut-shaped distribution, the test data in the wafer may also have, for example, a Mexican hat shape (high in the middle, low around the perimeter), a bowl shape (low in the middle, high around the perimeter), or other regular distribution structures with annular or radial shapes.

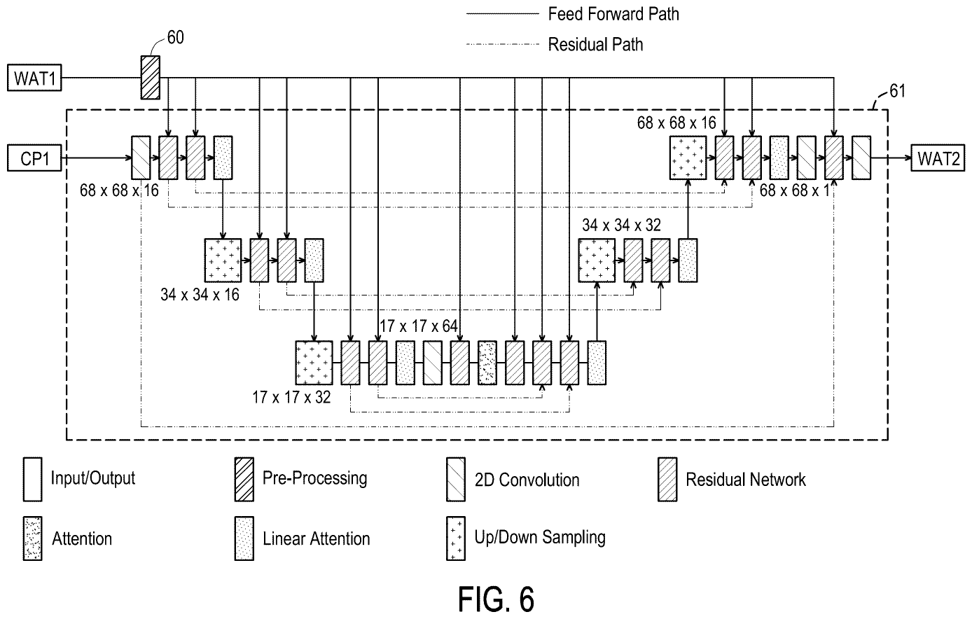

FIG. 6 is a schematic diagram of an artificial intelligence model 61 and a pre-processing 60 according to an embodiment of the disclosure. In the embodiment, the pre-processing 60 is, for example, a sinusoidal positioning embedding or an MLP, and the artificial intelligence model 61 is, for example, a VAE, a cVAE, a U-Net, an MLP, etc. In the embodiment shown in the figure, the artificial intelligence model 61 is described using a U-Net as an exemplary embodiment, but the disclosure is not limited thereto. The U-Net that serves as the artificial intelligence model 61 includes an input/output unit, a 2D convolution unit, a residual network unit, an attention unit, a linear attention unit, and an up/down sampling unit.

As shown in FIG. 6, the test data WAT1 may be provided to the pre-processing 60. The pre-processing 60 may process position information of the test data WAT1 and convert to positional embedding vectors in order to provide to the residual network units of the artificial intelligence model 61. In the embodiment, the left side of the artificial intelligence model 61 is an encoder, and the right side is a corresponding and symmetrical decoder. The artificial intelligence model 61 may receive the CP data CP1 and perform computation according to the positional embedding vectors. As the computation process proceeds, the encoder of the artificial intelligence model 61 may gradually reduce the dimension of the CP data CP1 to extract features. The decoder may gradually highlight the features to generate the predicted WAT data WAT2 in the process of restoring resolution. In the overall encoding and decoding process, the U-Net may further be provided with residual paths of several skip connections configured to help message transmission through direct connections to avoid a result of an excessively deep model structure leading to vanishing gradient. In addition, during the computation process of the overall artificial intelligence model 61, the pre-processing may encode the position message in the WAT data WAT1 to generate the positional embedding vector, and provide to the multiple residual networks of the artificial intelligence model 61 to allow the artificial intelligence model 61 to construct according to the WAT data WAT1.

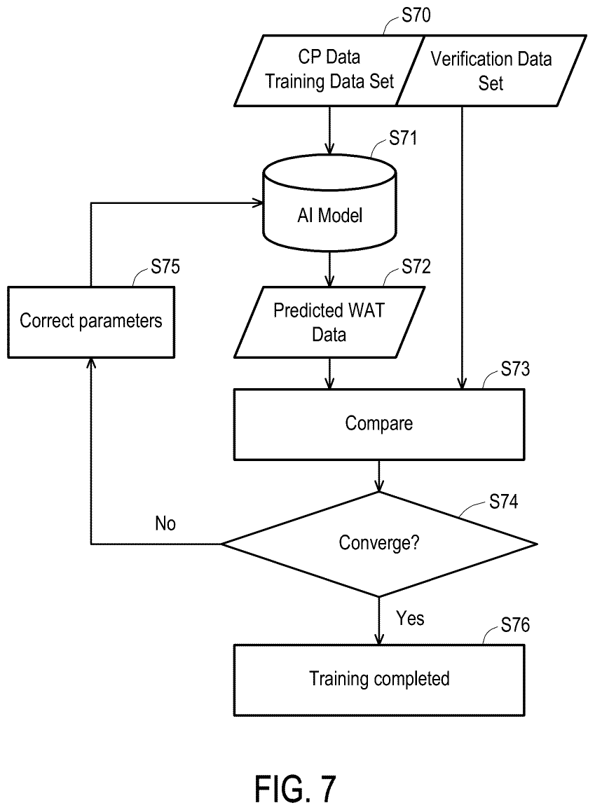

FIG. 7 is a flow chart of a training method for an artificial intelligence model. The training method in FIG. 7 may be used, for example, to train the artificial intelligence model 110 stored in the memory 11 in FIG. 1, or the artificial intelligence model 41 in FIG. 4, or the artificial intelligence model 61 in FIG. 6. Moreover, the training method in FIG. 7 may be executed through, for example, the electronic device 1 in FIG. 1, or through other electronic devices with similar computing capabilities to obtain a trained artificial intelligence model, and then save in the electronic device 1 in FIG. 1.

The training method in FIG. 7 includes steps S70 to S76. In step S70, a training data set and a verification data set may be obtained. Specifically, a CP data, the training data set and the verification data set are test data on the same wafer. For training and verification, different positions of the same wafer may be tested first to obtain WAT measurement data sets with more data points. The measurement data sets may be further split into the training data sets and the verification data sets. For example, the quantities of the training data sets and the verification data sets may be split in a quantity ratio of 2:8. Alternatively, the measurement data of 13 data points in the measurement data set may be split into the training data sets, and the measurement data of, for example, 78 data points may be split into the verification data sets. In some embodiments, the training data sets and the verification data sets may partially overlap or not overlap at all. In other embodiments, the quantity of data points in the training data sets and the verification data sets may be adjusted according to different design needs.

In step S71, the CP data and the training data sets of the same wafer may be provided to the artificial intelligence model for training. Though not explicitly shown in FIG. 7, in the embodiment, the training data sets may also be pre-processed to encode position information of the training data sets as positional embedding vectors and provide to the artificial intelligence model. Therefore, the artificial intelligence model may perform predictions according to the training data sets and the corresponding positional embedding vectors, and generate predicted WAT data in step S72. Since the pre-processing and the artificial intelligence model may both be MLPs, the training may be performed to both the pre-processing and the artificial intelligence model at the same time during the training process.

Next, in step S73, the difference between the predicted WAT data and the verification data sets may be compared. Generally speaking, the loss function may be used to represent and quantify the difference between the predicted WAT data and the verification data in this step, so as to determine whether the predicted WAT data converges to the verification data sets or converges to a preset range.

In step S74, when it is determined that the prediction data has not converged to the verification data, or when the difference between the prediction data and the verification data exceeds the preset range, it may be determined that the training of the artificial intelligence model on the batch of data has not been completed, that is, step S75 is entered.

In step S75, parameters or weights in the artificial intelligence model may be corrected according to the difference between the prediction data and the verification data to train again according to the training data sets and the verification data sets after the artificial intelligence model is adjusted.

On the contrary, when it is determined that the prediction data converges to the verification data, or when the difference between the prediction data and the verification data is within a preset range, it may be determined that the training of the artificial intelligence model on the batch data has been completed, that is, step S76 is entered.

In some embodiments, after the training is completed for the batch, a next batch of test data may be further received to continue the training of the artificial intelligence model until the training of all test data has been input into the artificial intelligence model and the training is completed. In some embodiments, the training method in FIG. 7 may be further applied to retrain the artificial intelligence model to allow weight data of the artificial intelligence model to be dynamically adjusted for the production of each wafer and each lot to generate more precise predicted WAT data and adapt to the changes in characteristics of different wafer production lots. In some embodiments, the predicted WAT data may be used as a reference to adaptively fine-tune the circuit in order to overcome process imperfections and improve yield, thereby enhancing circuit performance.

In summary, the method and the electronic device for predicting wafer test data of the disclosure may perform a pre-processing on the test data to appropriately represent the position information of the test data as positioning-embedding information. In this way, the artificial intelligence model can generate prediction data of the entire wafer test data distribution according to less test data in a condition where the position information is obtained.

What is claimed is:

1. A method for predicting wafer test data, comprising:
performing a pre-processing on a wafer acceptance test (WAT) data of a wafer to convert a plurality of position information of the WAT data on the wafer to a plurality of positional embedding vectors, wherein the WAT data has a first quantity of data points; and
inputting a chip probing (CP) data and the positional embedding vectors of the wafer into an artificial intelligence model to allow the artificial intelligence model to generate a predicted WAT data of the wafer, wherein the predicted WAT data has a second quantity of data points greater than the first quantity.

2. The method according to claim 1, wherein the CP data and the predicted WAT data have data points of a full map of the wafer.

3. The method according to claim 1, the pre-processing is a sinusoidal positioning embedding or a multilayer perceptron model.

4. The method according to claim 1, the artificial intelligence model is a multilayer perceptron model, and the positional embedding vectors are a plurality of residual network (ResNet) units provided to the artificial intelligence model.

5. The method according to claim 4, wherein the multilayer perceptron model is one of a VAE (variational autoencoder) model, a cVAE (conditional variational autoencoder) model, and a U-net model.

6. The method according to claim 1, wherein the wafer is a first wafer, and a CP data, a WAT data and a predicted WAT data of the first wafer are respectively a first CP data, a first WAT data and a first predicted WAT data, and the method further comprises the following steps to train the pre-processing and the artificial intelligence model:
splitting a second WAT data of a second wafer into a training WAT data and a verification WAT data;
inputting the training WAT data of the second wafer into the pre-processing, and inputting a second CP data of the second wafer into the artificial intelligence model to allow the artificial intelligence model to generate a second predicted WAT data; and
comparing the second predicted WAT data and the verification WAT data to adjust the pre-processing and the artificial intelligence model.

7. The method according to claim 1, wherein the WAT data records a mean value message of the wafer, and parameters of the artificial intelligence model are dynamically adjusted according to the predicted WAT data.

8. An electronic device for predicting wafer test data, comprising:
a memory, storing a command; and
a processing circuit, coupled to the memory, wherein the processing circuit is configured to access the command to execute an artificial intelligence model for:
performing a pre-processing on a wafer acceptance test (WAT) data of a wafer to convert a plurality of position information of the WAT data on the wafer to a plurality of positional embedding vectors, wherein the WAT data has a first quantity of data points; and
inputting a chip probing (CP) data and the positional embedding vectors of the wafer into the artificial intelligence model to allow the artificial intelligence model to generate a predicted WAT data of the wafer, wherein the predicted WAT data has a second quantity of data points greater than the first quantity.

9. The electronic device according to claim 8, wherein the CP data and the predicted WAT data have data points of a full map of the wafer.

10. The electronic device according to claim 8, wherein the pre-processing is a sinusoidal positioning embedding or a multilayer perceptron model.

11. The electronic device according to claim 8, wherein the artificial intelligence model is a multilayer perceptron model, and the positional embedding vectors are a plurality of residual network (ResNet) units provided to the artificial intelligence model.

12. The electronic device according to claim 11, wherein the multilayer perceptron model is one of a VAE (variational autoencoder) model, a cVAE (conditional variational autoencoder) model, and a U-net model.

13. The electronic device according to claim 8, wherein the wafer is a first wafer, and a CP data, a WAT data and a predicted WAT data of the first wafer are respectively a first CP data, a first WAT data and a first predicted WAT data, and the processing circuit further executes the following steps to train the pre-processing and the artificial intelligence model:
splitting a second WAT data of a second wafer into a training WAT data and a verification WAT data;
inputting the training WAT data of the second wafer into the pre-processing, and inputting a second CP data of the second wafer into the artificial intelligence model to allow the artificial intelligence model to generate a second predicted WAT data; and
comparing the second predicted WAT data and the verification WAT data to adjust the pre-processing and the artificial intelligence model.
